(19) United States
(12) Patent Application Publication
(10) Pub. No.: US 2024/0055822 A1
(43) Pub. Date: Feb. 15, 2024

(54) REDUCING SPECTRAL VARIANCE OF A LASER SOURCE

(71) Applicant: Meta Platforms Technologies, LLC, Menlo Park, CA (US)

(72) Inventor: Joseph Mansour, Apex, NC (US)

(21) Appl. No.: 17/884,427

(22) Filed: Aug. 9, 2022

(51) Int. Cl. H01S 3/08

(52) U.S. Cl. CPC H01S 3/08063; H01S 3/08081

(57) ABSTRACT

A laser source includes an optical resonator including first and second reflectors having first and second reflection spectral bands. A gain medium is disposed in the optical resonator. The gain medium has a gain spectrum. Center wavelengths of at least two of: the first reflection spectral band; the second reflection spectral band; or the gain spectrum are offset relative to each other for reduction of a spectral variance of the laser source. For example, the first and the second reflection spectral bands may be offset relative to one another to form an overlap area above a lasing threshold. The lasing is limited to the overlap area. When the overlap area accommodates a single lasing mode, the output emission of the laser source is monochromatic.

### TECHNICAL FIELD

The present disclosure relates to lasers and laser-based light sources and illuminators usable in visual display systems.

### BACKGROUND

Visual displays provide information to viewer(s) including still images, video, data, etc. Visual displays have applications in diverse fields including entertainment, education, engineering, science, professional training, advertising, to name just a few examples. Some visual displays e.g. TV sets display images to several users, and some visual display systems e.g. near-eye displays (NEDs) are intended for individual users.

An artificial reality system generally includes an NED (e.g., a headset or a pair of glasses) configured to present content to a user. The near-eye display may display virtual objects or combine images of real objects with virtual objects, as in virtual reality (VR), augmented reality (AR), or mixed reality (MR) applications. For example, in an AR system, a user may view images of virtual objects (e.g., computer-generated images (CGIs)) superimposed with the surrounding environment by seeing through a “combiner” component. The combiner of a wearable display is typically transparent to external light but includes some light routing optic to direct the display light into the user's field of view.

Because a display of HMD or NED is usually worn on the head of a user, a large, bulky, unbalanced, and/or heavy display device with a heavy battery would be cumbersome and uncomfortable for the user to wear. Consequently, head-mounted display devices can benefit from a compact and efficient configuration, including stable and efficient light sources and illuminators providing illumination of a microdisplay panel. Laser-based light sources, although being compact and efficient, may exhibit instabilities such as emission wavelength drift or jitter.

### BRIEF DESCRIPTION OF THE DRAWINGS

Exemplary embodiments will now be described in conjunction with the drawings, in which:

FIG. 1 is a side cross-sectional view of a laser source;

FIG. 2A is a gain spectrum of the laser source of FIG. 1, showing a lasing threshold;

FIG. 2B is the gain spectrum and the lasing threshold of FIG. 2A, overlapped with a set of longitudinal modes of an optical resonator of the laser source of FIG. 1;

FIG. 2C is a spectral plot showing spectral shaping of generated light by one of reflectors of an optical resonator of the laser source of FIG. 1;

FIG. 2D is a spectral plot illustrating a reduction of spectral variance and/or spectral bandwidth of the generated light by introducing a wavelength offset between the gain spectrum of the laser medium and a reflection spectrum of a reflector of the optical resonator;

FIG. 2E is a spectral plot illustrating a reduction of spectral variance of the generated light by introducing an offset between reflection spectra of opposed reflectors of the optical resonator of the laser source of FIG. 1;

FIG. 3 is a spectral plot of gain superimposed with reflection spectra of the opposed reflectors;

FIG. 4 is a side cross-sectional view of a laser source of this disclosure with light generated in both directions;

FIG. 5 is a side cross-sectional view of a side-emitting laser diode of this disclosure;

FIG. 6 is a spectral plot of gain superimposed with offset reflection spectra of the opposed reflectors and longitudinal modes of the optical resonator formed by the opposed reflectors of the laser diode of FIG. 5, the longitudinal modes including only one mode in an overlap area formed by the offset reflection spectra;

FIG. 7 is a side cross-sectional view of a display device illuminated by a laser source of this disclosure;

FIG. 8 is a view of wearable display of this disclosure having a form factor of a pair of eyeglasses; and

FIG. 9 is a three-dimensional view of a head-mounted display (HMD) of this disclosure.

### DETAILED DESCRIPTION

While the present teachings are described in conjunction with various embodiments and examples, it is not intended that the present teachings be limited to such embodiments. On the contrary, the present teachings encompass various alternatives and equivalents, as will be appreciated by those of skill in the art. All statements herein reciting principles, aspects, and embodiments of this disclosure, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

As used herein, the terms “first”, “second”, and so forth are not intended to imply sequential ordering, but rather are intended to distinguish one element from another, unless explicitly stated. Similarly, sequential ordering of method steps does not imply a sequential order of their execution, unless explicitly stated. In FIGS. 1, 4, and 5, similar reference numerals denote similar elements.

A laser source may be used as a light source in a display device. For example, a laser source may be used to illuminate a micro-display panel of a near-eye display. A laser source may also be used as a light source in a scanning projector forming an image to be displayed by scanning or rastering a light beam emitted by the laser source. Among the benefits of utilization of a laser source in a visual display is compactness, high directivity, high efficiency, high spectral purity. On the other hand, lasers, especially mass-produced lasers, may be prone to emission wavelength drift, low coherence, mode hopping, and other instabilities.

Wavelength drift of laser sources is often caused by spectral gain drift of the laser gain medium. For example, in laser diodes, the gain spectral profile and a center wavelength of the gain band may depend on parameters such as temperature and driving current. Optical resonators may be configured to provide some degree of stabilization of the lasing wavelength. Narrowband spectral filters, or cascades of progressively more narrow spectral filters centered on a desired wavelength, may be included in the optical train. However, narrowband filters may be costly to manufacture, and may impact manufacturing yield, especially in laser types where the coatings are deposited directly onto the gain medium, such as in side-emitting laser diodes.

In accordance with this disclosure, spectral variance of a laser source may be reduced by providing spectral offset between reflection bands of the laser resonator's reflectors and, optionally, the gain spectral band of the laser's gain medium. Advantageously, spectrally offsetting reflection bands of the resonator's reflectors results in the narrowing and stabilization of the laser emission spectral band without resorting to complex and expensive narrowband coatings or narrowband spectral filters in the laser's optical cavity. The narrow emission bandwidth may be achieved by providing an offset between reflection spectral bands of the opposed mirrors of an optical resonator or cavity, to leave relatively narrow spectral band above the lasing threshold. In this manner, the narrow spectral band of laser emission may be formed without having to rely on complex multilayer dielectric coating structures.

In accordance with the present disclosure, there is provided a laser source comprising an optical resonator having opposed first and second reflectors with first and second reflection spectral bands, respectively, and a gain medium in the optical resonator, the gain medium having a gain spectrum. Center wavelengths of at least two of: the first reflection spectral band; the second reflection spectral band; or the gain spectrum are offset relative to each other for reduction of a spectral variance of the laser source. In some embodiments, a first of the at least two is the first reflection spectral band, and a second of the at least two is the gain spectrum. In some embodiments, a first of the at least two is the first reflection spectral band, and a second of the at least two is the second reflection spectral band.

A lasing spectrum of the laser source may be in an overlap area between the first and second reflection spectral bands, the overlap area being within the gain spectrum of the gain medium and above a lasing threshold of the laser source. The offset may be e.g. at least 20% of a lesser of a bandwidth of the first and second reflection bands or even at least 120% of the lesser of a bandwidth of the first and second reflection bands. A bandwidth of the overlap area may be e.g. less than 20% of a bandwidth of the gain spectrum above a lasing threshold of the laser source.

In embodiments where the laser source comprises a side-emitting laser diode, the first reflector may include a first optical coating at a first end facet of the side-emitting laser diode, the first coating having the first reflection spectral band. The second reflector may include a second optical coating at a second, opposite end facet of the side-emitting laser diode, the second coating having the second reflection spectral band. The first optical coating may be formed on the first end facet of the side-emitting laser diode, and the second optical coating may be formed on the second end facet of the side-emitting laser diode. The gain medium may include a quantum well layer of the side-emitting laser diode.

At least one of the first or second coatings may include a multilayer dielectric coating with a reflection bandwidth of less than 0.5 nm. The optical resonator may include only one longitudinal mode within an overlap area between the first and second reflection spectral bands and above a lasing threshold of the laser source. The first coating may have a peak reflectivity of greater than 70%, and the second coating may have a peak reflectivity of less than 30%.

In accordance with the present disclosure, there is provided a display device comprising any of the above laser sources as an illuminator. Center wavelengths of the first and second reflection spectral bands may be offset from one another for narrowing a lasing spectrum of the laser source, and the lasing spectrum may be in an overlap area between the first and second reflection spectral bands. The overlap area may be within the gain spectrum of the gain medium.

In accordance with the present disclosure, there is further provided a side-emitting laser diode comprising an optical resonator comprising an output coupler for out-coupling laser emission and a rear reflector opposite the output coupler, and a gain medium in the optical resonator, the gain medium having a gain spectrum. The rear reflector includes a first optical interference filter having a reflection spectral band with a bandwidth narrower than 10% of a bandwidth of the gain spectrum above a lasing threshold, for defining a lasing spectrum. The output coupler includes a second optical interference filter having a reflection spectral band with maximum reflectivity of at least 30%.

In some embodiments, the bandwidth of the first optical interference filter is less than 0.5 nm FWHM. Center wavelengths of the reflection spectral bands of the first and second optical interference filters may be offset from one another for narrowing the lasing spectrum. The lasing spectrum may be in an overlap area between the reflection spectral bands, and the overlap area may be within the gain spectrum of the gain medium. The side-emitting laser diode may include a laser diode chip, where the first and second optical interference filters are disposed on opposite sides of the laser diode chip.

Referring now to FIG. 1, a laser source 100 includes an optical resonator 102 comprising opposed first 111 and second 112 reflectors. A gain medium 104 is disposed in the optical resonator 102. The first reflector 111 may be a full reflector, i.e. a 100% reflector, and the second reflector 112 may be a partial reflector that transmits through a portion 106 of generated laser light 108.

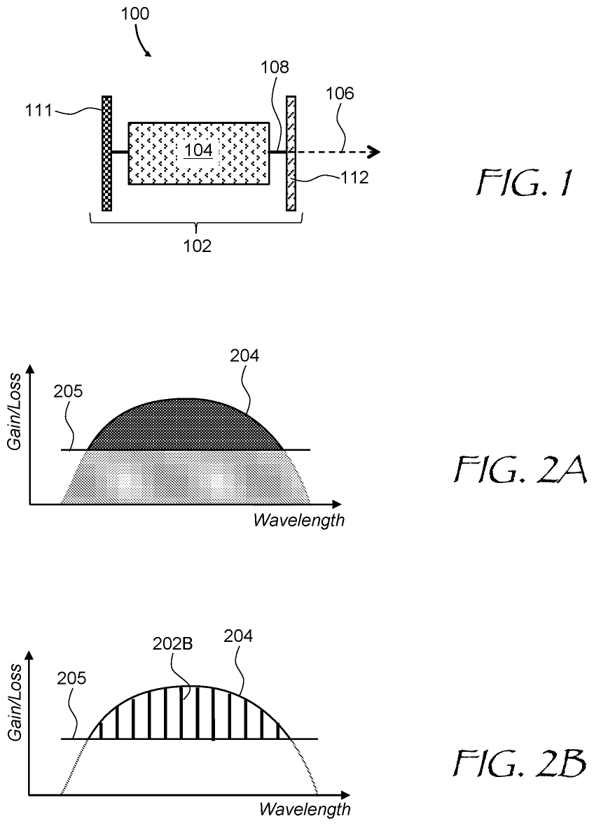

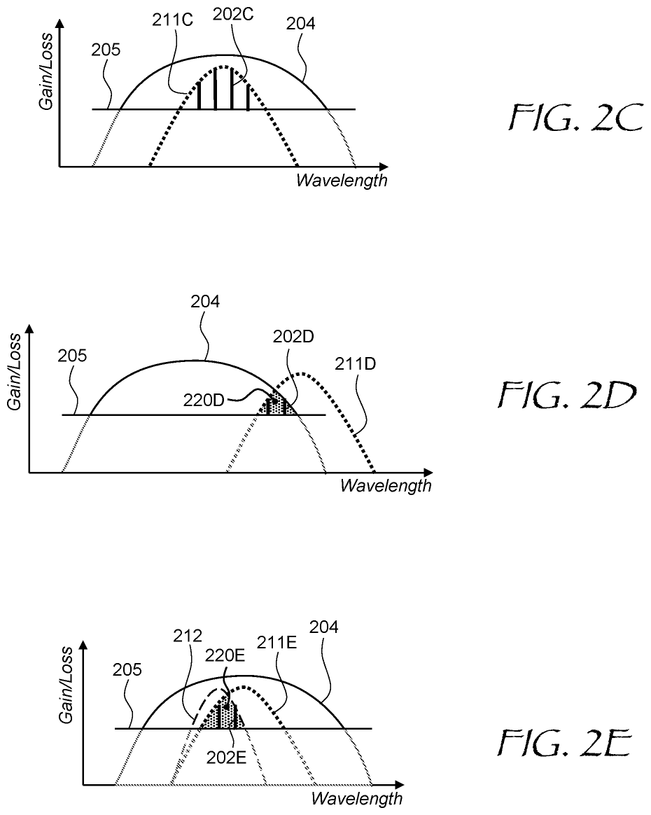

Referring to FIG. 2A with further reference to FIG. 1, the gain medium 104 has a gain spectrum 204. A lasing threshold 205 indicates a level of spectral gain, above which the optical gain by the gain medium 104 is higher than optical loss of the optical resonator 102, and thus lasing by the laser source 100 is possible. The lasing may occur on any of longitudinal modes 202B of the optical resonator 102. The longitudinal modes 202B are depicted in FIG. 2B. The frequency spacing between the longitudinal modes 202B is defined by a free spectral range of an optical cavity formed by the reflectors 111, 112 of the optical resonator 102, while the lasing modes of the laser source 100 are selected by the portion of the gain spectrum 204 above the lasing threshold 205. FIG. 2B shows all lasing modes corresponding to longitudinal lasing modes above the lasing threshold 205.

Turning to FIG. 2C with further reference to FIG. 1, one of the first 111 or second 112 reflectors of the optical resonator 102 may be made wavelength-selective to limit the emitted wavelength range of the laser source 100. By way of a non-limiting example, the first reflector 111 may have a first reflection spectrum 211C. Longitudinal lasing modes 202C will be limited by the first reflection spectrum 211C, as illustrated. By making the first reflector 111 to have a narrow enough reflection spectrum, the lasing bandwidth may be limited to a few or even one longitudinal modes 202C.

The number of lasing modes may be limited by utilizing a slope of the gain spectrum 204. Referring for a non-limiting illustrative example to FIG. 2D, a first reflection spectrum 211D of the first reflector 111 (FIG. 1) may be offset relative to the gain spectrum 204, leaving only two lasing modes 202D in an overlap area 220D (a shaded area in FIG. 2D) between the first reflection spectrum 211D and the gain spectrum 204 and above the lasing threshold 205. In other words, a relative offset of center wavelengths of the first reflection spectrum 211D and of the gain spectrum 204 may be used to reduce a spectral bandwidth of the laser emission, i.e. the transmitted portion 106 of the generated laser light 108 (FIG. 1).

In many laser systems and especially in semiconductor lasers, the gain spectrum 204 is influenced by various factors such as pumping conditions, temperature, lasing output etc., making wavelength of the emitted light drift with time. In such systems, a reflection spectrum of the first 111 and/or second 112 reflectors of the optical resonator, or lasing cavity 102 may be relied upon to reduce spectral variance of the output emission of the laser source. The reflection spectra of the first 111 and/or second 112 reflectors are often much less dependent on temperature and lasing conditions than the gain spectrum 204 itself.

Referring for a non-limiting illustrative example to FIG. 2E, a first reflection spectrum 211E of the first reflector 111 is offset in wavelength relative to a second reflection spectrum 212 of the second reflector 112. The lasing is possible in an overlap area 220E (a shaded area in FIG. 2E) between the first 211E and second 212 reflection spectra, and above the lasing threshold 205. The lasing may occur at the longitudinal modes 202E.

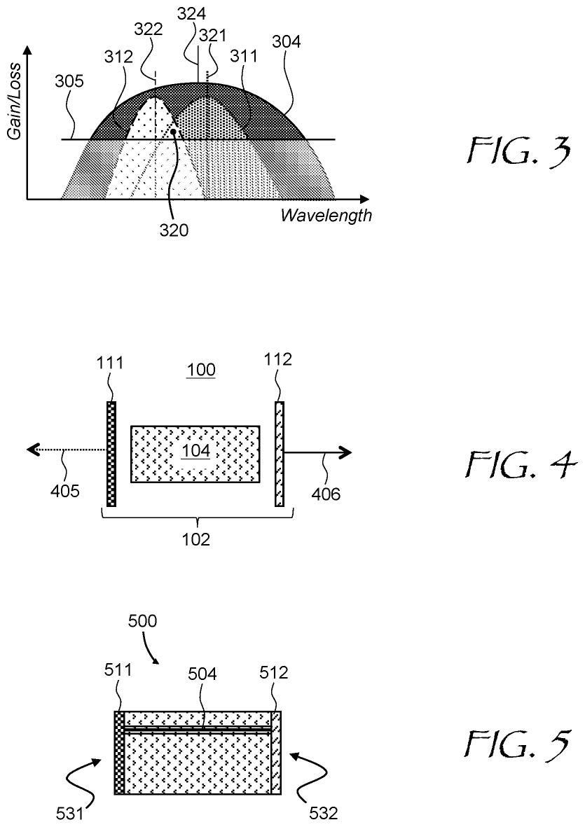

In some embodiments, the reflection and the gain spectral may be all offset from one another, or at least some of them may be offset relative to one another. Referring to FIG. 3 with further reference to FIG. 1, center optical frequencies or center wavelengths of: a first reflection spectral band 311 of the first reflector 111; a second reflection spectral band 312 of the second reflector 112; and a gain spectrum 304 of the gain medium 104 are offset relative to each other for the purpose of reduction of a spectral variance of the laser source 100. Specifically, a first center wavelength 321 of the first reflection spectral band 311 is offset from a second center wavelength 322 of the second reflection spectral band 312 and from a center wavelength 324 of the gain spectrum 304. In this case, the lasing occurs in a spectral band 320 defined by an overlap of the first 311 and second 312 spectral bands, which is still above a lasing threshold 305 of the laser source 100.

To provide a more narrowband output emission of the laser device 100, center optical frequencies or wavelengths of at least two of: the first reflection spectral band 311; the second reflection spectral band 312; or the gain spectrum 304 may be offset relative to each other for reduction of a spectral variance of the laser source 100. For example, in FIG. 2D, the gain spectrum 204 is offset relative to the first reflection spectrum 211D of the first reflector 111. In FIG. 2E, the first reflection spectrum 211D of the first reflector 111 is offset relative to the second reflection spectrum 212 of the second reflector 112, the overlap area 220E being within the gain spectrum 204 of the gain medium 104 and above the lasing threshold 205 of the laser source 100.

In comparison with the situation of FIG. 2C where the emission spectrum is determined by the reflection band of the first reflector 111 alone, the configuration of FIG. 2E may be advantageous in that both the first 211E and second 212 reflection spectra need not be narrowband, and therefore the respective first 111 and second 112 reflectors may be simple and inexpensive dielectric coatings or dielectric stacks of a few layers only. Thus, the configuration of FIG. 2E enables a stable narrowband laser output without resorting to usage of expensive narrowband coatings or other spectral elements.

The magnitude of the offset between the first center wavelengths of the reflection bands of the first 111 and second 112 reflectors may be e.g. at least 20% of a lesser of a bandwidth of the first and second reflection bands, or at least 120% of the lesser of a bandwidth of the first and second reflection bands. In some embodiments, a bandwidth of the overlap area 220E of FIG. 2E or 320 of FIG. 3 is less than 20% of a bandwidth of the gain spectrum 204 or 304 above the lasing threshold 205 or 305 of the laser source 100.

FIG. 4 illustrates the spectral distribution of emitted light of the laser device 100 for a case when both the first 111 and second 112 reflectors are wavelength-selective reflectors having reflective spectral bands offset in wavelength or optical frequency. Output laser emission 406 out-coupled from the second reflector 112 will have the spectral composition of longitudinal modes within the overlap area 220E or 320. The second reflector functions as an output coupler of the laser source 100. Some of the emission, e.g. amplified spontaneous emission 405, may exit the first reflector 111, and will have a spectral composition of the gain spectrum 204 or 304 minus the first reflection band 211E or 311.

Turning to FIG. 5 with further reference to FIG. 1, a side-emitting laser diode 500 of FIG. 5 is similar to the laser source 100 of FIG. 1, and includes similar elements. The side-emitting laser diode 500 of FIG. 5 includes a first optical coating 511 at a first end facet or side 531 of the side-emitting laser diode 500, and a second optical coating 512 at a second, opposite end facet or side 532 of the side-emitting laser diode 500. The first optical coating 511 performs the function of the first reflector 111, and the second optical coating 512 performs the function of the second reflector 112 of the laser device 100 of FIG. 1.

The first optical coating 511 may be formed, e.g. deposited, on the first end facet 531, and the second optical coating may be formed, e.g. deposited, on the second end facet 532 of the side-emitting laser diode 500. The first 511 and/or second 512 coatings may be e.g. multilayer dielectric coatings on opposite sides, or end facets, of a laser diode chip. A gain medium of the side-emitting laser diode 500 may include a p-n region, which may include a quantum well layer 504. Reflection bandwidth of the first and/or second multilayer dielectric coating may be less than 10 nm; 2 nm; or as small as 0.5 nm or less in some embodiments. By way of a non-limiting example, the first coating 511 may have a peak reflectivity of greater than 70%, and the second coating 512 may have a peak reflectivity of less than 30%.

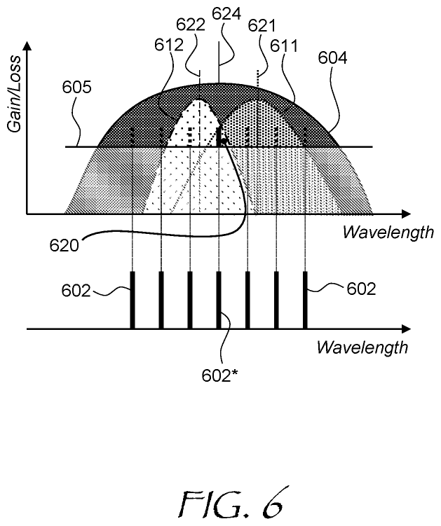

Referring now to FIG. 6 with further reference to FIG. 5, a spectral plot of gain 604 of the gain medium, e.g. the quantum well layer 504 of the side-emitting laser diode 500, is superimposed with first 611 and second 612 reflection spectra of the first 511 and second 512 optical coatings of the side-emitting laser diode 500. The gain spectral plot 604 has a center wavelength 624. Center wavelengths 621 and 622 of the first 611 and second 612 reflection spectra are offset relative to one another such that only one longitudinal optical mode 602* out of a plurality of longitudinal optical modes 602 (bottom portion of FIG. 6) is disposed within an overlap area 620 between the first 611 and second 612 reflection spectra and above a lasing threshold 605. Thus, only one longitudinal optical mode 602 may be amplified, causing the side-emitting laser diode 500 to generate output emission in a single longitudinal mode. This may be achieved without having to rely on complicated cascaded narrowband optical filters, making the side-emitting laser diode 500 a highly manufacturable and inexpensive monochromatic laser source. A singlemode operation of the side-emitting laser diode 500 may also be facilitated by shortening an optical cavity formed by the first 511 and second 512 optical coatings, i.e. by shortening the length of the side-emitting laser diode 500 between the first 511 and second 512 optical coatings. For example, in some embodiments the length may be shortened to 1 mm or less, or even to 0.5 mm or less.

The emission bandwidth of the side-emitting laser diode 500 may also be achieved by providing a rear reflector, i.e. the first optical coating 511 in FIG. 5, having a very narrow spectral bandwidth. To that end, the first optical coating 511 may include a first optical interference filter having a reflection spectral band with a bandwidth narrower than 10% of a bandwidth of the gain spectrum above a lasing threshold, for defining a lasing spectrum. In such a configuration, the exit coupler or second optical coating 512 may include a second optical interference filter having a broad reflection spectral band with maximum reflectivity of at least 30%. Center wavelengths of the reflection spectral bands of the first and second optical interference filters may be offset from one another for narrowing the lasing spectrum, narrowing the lasing to an overlap area between the reflection spectral bands 611 and 612 as illustrated in FIG. 6. The overlap area 620 needs to remain within the gain spectrum of the gain medium for the lasing to take place. In some embodiments, the bandwidth of the first optical interference filter may be solely relied upon for spectral narrowing, e.g. it may be e.g. less than 0.5 nm FWHM, whereas the bandwidth of the second optical interference filter may remain at least 5 nm or broader.

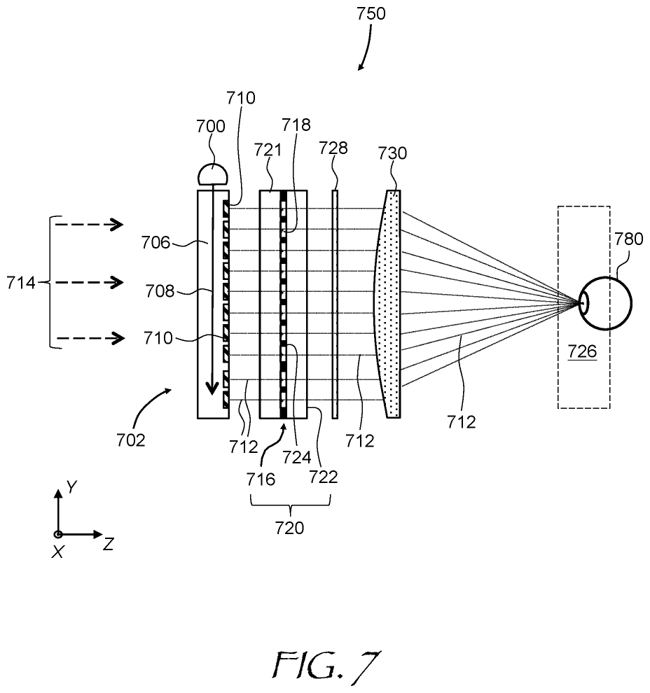

Referring now to FIG. 7, a display device 750 includes an illuminator 702 having a light source 700, which may include any of the laser sources described herein, e.g. the laser source 100 of FIG. 1, FIG. 4, and/or the side-emitting laser diode 500 of FIG. 5, providing narrowband or monochromatic laser light of well-defined polarization. The light source 700 (FIG. 7) is coupled to a transparent lightguide 706 for spreading light 708 emitted by the light source 700 in a plane parallel to the transparent lightguide 706, i.e. in XY plane. An array of gratings 710 is optically coupled to the transparent lightguide 706 for out-coupling portions 712 of the light 708 propagating in the transparent lightguide 706. The gratings 710 may be directly supported by the transparent lightguide 706, e.g. they may be immersed into the transparent lightguide 706, or they may rest on the transparent lightguide 706. Herein, the term “transparent lightguide” means that the lightguide propagates at least a useful portion, e.g. 10% or more, of ambient light 714, as well as other light that may propagate directly through the transparent lightguide 706.

The display device 750 further includes a display panel, e.g. a liquid crystal (LC) display panel 720 including an LC layer 716 sandwiched between opposed substrates 721 and 722. The LC display panel 720 is disposed downstream of the illuminator 702. The LC layer 716 includes an array of polarization-tuning pixels 718 in a thin layer of LC fluid between the first 721 and second 722 substrates of the LC display panel 720. The polarization-tuning pixels 718 may be formed e.g. by an array of transparent electrode segments supported by the first substrate 721, and by a common backplane electrode supported by the second substrate 722. The first 721 and/or second 722 substrates may also include a grid layer 724 adjacent the LC layer 716, for defining boundaries between the polarization tuning pixels 718. Herein, the term “polarization tuning” includes polarization rotation, changing ellipticity and/or handedness of circular or elliptically polarized light, etc.; in other words, any change of the state of polarization of incoming light, the change being controllable by application of an external signal to a particular areas of the LC layer 716.

In the display device 750, positions of the gratings 710 may be coordinated with positions of the polarization-tuning pixels 718 to propagate the portions 712 of the light 708 out-coupled from the transparent lightguide 706 by the gratings 710 through the corresponding polarization-tuning pixels 718. Herein, the term “coordinated positions” when applied to elements of two arrays of elements means that the positions of the elements of the two arrays in XY plane overlap or correspond to each other, e.g. have equal X-pitch and Y-pitch, or more generally having X-pitch of the first array an integer multiple of the X-pitch of the second array or vice versa, and having Y-pitch of the first array an integer multiple of the Y-pitch of the second array or vice versa.

The display device 750 may further include a polarizer 728 downstream of the LC layer 716. The polarizer 728 may be configured to pass through light in a first polarization state while rejecting light in a second, orthogonal polarization state. The portions 712 of the light 708 propagated through the polarization-tuning pixels 718 will be attenuated by the polarizer 728 depending on their respective polarization state that may be controllably changed by the polarization-tuning pixels 718. For example, the first polarization state may be a linear polarization, e.g. Y-polarization, and the second polarization state may be an orthogonal linear polarization i.e. X-polarization, or vice versa. In other embodiments, the first polarization component may be left-circular polarization, and the second polarization component may be a right-circular polarization, or vice versa. The high polarization state afforded by the laser-based light source 700 may be configured to emit the light 108 in the first polarization state. The transparent lightguide 706 may be constructed to substantially preserve the polarization state of the light it spreads in XY plane.

The display device 750 may further include an ocular lens 730 in an optical path between the LC layer 716 and an eyebox 726, downstream of the polarizer 728. The purpose of the ocular 730 is to convert an image in linear domain at the LC layer 716 into an image on angular domain at the eyebox 726 where it can be directly observed by a user's eye 780. More generally, the ocular lens 730 is but one type of an offset-to-angle ocular element which may be a refractive, reflective, and/or diffractive element having optical power, i.e. focusing or defocusing power. As implied by its name, the offset-to-angle ocular element performs the function of converting an image in linear domain at the LC layer 716 into an image on angular domain at the eyebox 726. The image in angular domain may be directly observed by the user's eye 780 at the eyebox 726 of the display device 750.

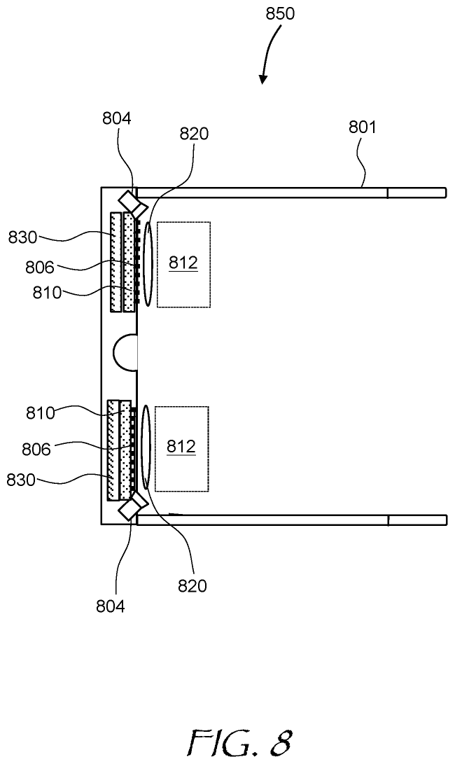

Referring to FIG. 8, a virtual reality (VR) near-eye display 850 includes a frame 801 supporting, for each eye: an illuminator 830 including any of the laser sources disclosed herein; a display panel 810 including an array of display pixels; and an ocular lens 820 for converting the image in linear domain generated by the display panel 810 into an image in angular domain for direct observation at an eyebox 812. A plurality of eyebox illuminators 806, shown as black dots, may be placed around the display panel 810 on a surface that faces the eyebox 812. An eye-tracking camera 804 may be provided for each eyebox 812.

The purpose of the eye-tracking cameras 804 is to determine position and/or orientation of both eyes of the user. The eyebox illuminators 806 illuminate the eyes at the corresponding eyeboxes 812, allowing the eye-tracking cameras 804 to obtain the images of the eyes, as well as to provide reference reflections i.e. glints. The glints may function as reference points in the captured eye image, facilitating the eye gazing direction determination by determining position of the eye pupil images relative to the glints images. To avoid distracting the user with the light of the eyebox illuminators 806, the latter may be made to emit light invisible to the user. For example, infrared light may be used to illuminate the eyeboxes 812.

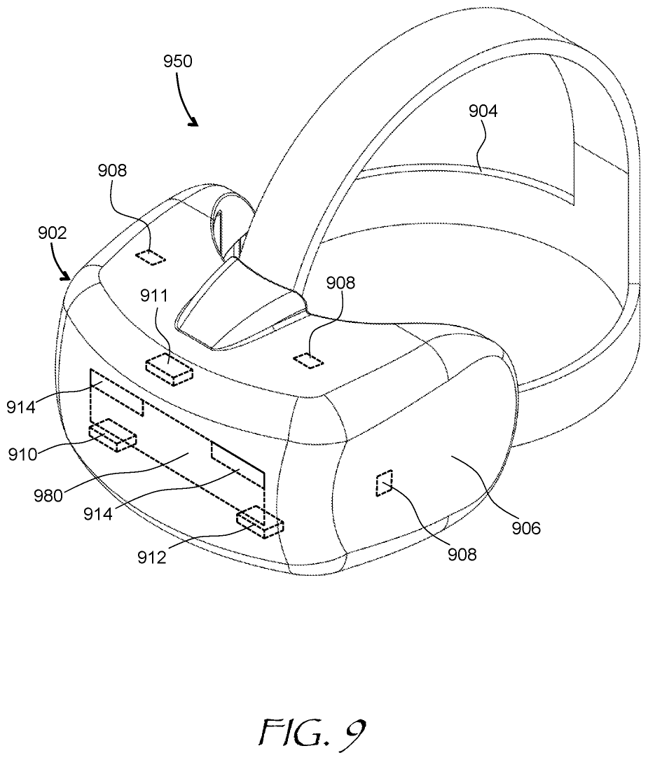

Turning to FIG. 9, an HMD 950 is an example of an AR/VR wearable display system which encloses the user's face, for a greater degree of immersion into the AR/VR environment. The HMD 950 may generate the entirely virtual 3D imagery. The HMD 950 may include a front body 902 and a band 904 that can be secured around the user's head. The front body 902 is configured for placement in front of eyes of a user in a reliable and comfortable manner. A display system 980 may be disposed in the front body 902 for presenting AR/VR imagery to the user. The display system 980 may include any of the display devices and laser sources disclosed herein. Sides 906 of the front body 902 may be opaque or transparent.

In some embodiments, the front body 902 includes locators 908 and an inertial measurement unit (IMU) 910 for tracking acceleration of the HMD 950, and position sensors 912 for tracking position of the HMD 950. The IMU 910 is an electronic device that generates data indicating a position of the HMD 950 based on measurement signals received from one or more of position sensors 912, which generate one or more measurement signals in response to motion of the HMD 950. Examples of position sensors 912 include: one or more accelerometers, one or more gyroscopes, one or more magnetometers, another suitable type of sensor that detects motion, a type of sensor used for error correction of the IMU 910, or some combination thereof. The position sensors 912 may be located external to the IMU 910, internal to the IMU 910, or some combination thereof.

The locators 908 are traced by an external imaging device of a virtual reality system, such that the virtual reality system can track the location and orientation of the entire HMD 950. Information generated by the IMU 910 and the position sensors 912 may be compared with the position and orientation obtained by tracking the locators 908, for improved tracking accuracy of position and orientation of the HMD 950. Accurate position and orientation is important for presenting appropriate virtual scenery to the user as the latter moves and turns in 3D space.

The HMD 950 may further include a depth camera assembly (DCA) 911, which captures data describing depth information of a local area surrounding some or all of the HMD 950. The depth information may be compared with the information from the IMU 910, for better accuracy of determination of position and orientation of the HMD 950 in 3D space.

The HMD 950 may further include an eye tracking system 914 for determining orientation and position of user's eyes in real time. The obtained position and orientation of the eyes also allows the HMD 950 to determine the gaze direction of the user and to adjust the image generated by the display system 980 accordingly. The determined gaze direction and vergence angle may be used to adjust the display system 980 to reduce the vergence-accommodation conflict. The direction and vergence may also be used for displays' exit pupil steering as disclosed herein. Furthermore, the determined vergence and gaze angles may be used for interaction with the user, highlighting objects, bringing objects to the foreground, creating additional objects or pointers, etc. An audio system may also be provided including e.g. a set of small speakers built into the front body 902.

Embodiments of the present disclosure may include, or be implemented in conjunction with, an artificial reality system. An artificial reality system adjusts sensory information about outside world obtained through the senses such as visual information, audio, touch (somatosensation) information, acceleration, balance, etc., in some manner before presentation to a user. By way of non-limiting examples, artificial reality may include virtual reality (VR), augmented reality (AR), mixed reality (MR), hybrid reality, or some combination and/or derivatives thereof. Artificial reality content may include entirely generated content or generated content combined with captured (e.g., real-world) content. The artificial reality content may include video, audio, somatic or haptic feedback, or some combination thereof. Any of this content may be presented in a single channel or in multiple channels, such as in a stereo video that produces a three-dimensional effect to the viewer. Furthermore, in some embodiments, artificial reality may also be associated with applications, products, accessories, services, or some combination thereof, that are used to, for example, create content in artificial reality and/or are otherwise used in (e.g., perform activities in) artificial reality. The artificial reality system that provides the artificial reality content may be implemented on various platforms, including a wearable display such as an HMD connected to a host computer system, a standalone HMD, a near-eye display having a form factor of eyeglasses, a mobile device or computing system, or any other hardware platform capable of providing artificial reality content to one or more viewers.

The present disclosure is not to be limited in scope by the specific embodiments described herein. Indeed, other various embodiments and modifications, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A laser source comprising:
an optical resonator comprising opposed first and second reflectors having first and second reflection spectral bands, respectively; and
a gain medium in the optical resonator, the gain medium having a gain spectrum;
wherein center wavelengths of at least two of: the first reflection spectral band; the second reflection spectral band; or the gain spectrum are offset relative to each other for reduction of a spectral variance of the laser source.

2. The laser source of claim 1, wherein a first of the at least two is the first reflection spectral band, and a second of the at least two is the gain spectrum.

3. The laser source of claim 1, wherein a first of the at least two is the first reflection spectral band, and a second of the at least two is the second reflection spectral band.

4. The laser source of claim 3, wherein a lasing spectrum of the laser source is in an overlap area between the first and second reflection spectral bands, wherein the overlap area is within the gain spectrum of the gain medium and above a lasing threshold of the laser source.

5. The laser source of claim 4, wherein the offset is at least 20% of a lesser of a bandwidth of the first and second reflection bands.

6. The laser source of claim 5, wherein the offset is at least 120% of the lesser of a bandwidth of the first and second reflection bands.

7. The laser source of claim 4, wherein a bandwidth of the overlap area is less than 20% of a bandwidth of the gain spectrum above a lasing threshold of the laser source.

8. The laser source of claim 1, wherein:
the laser source comprises a side-emitting laser diode;
the first reflector comprises a first optical coating at a first end facet of the side-emitting laser diode, the first coating having the first reflection spectral band; and
the second reflector comprises a second optical coating at a second, opposite end facet of the side-emitting laser diode, the second coating having the second reflection spectral band.

9. The laser source of claim 8, wherein the first optical coating is formed on the first end facet of the side-emitting laser diode, and the second optical coating is formed on the second end facet of the side-emitting laser diode.

10. The laser source of claim 8, wherein the gain medium comprises a quantum well layer of the side-emitting laser diode.

11. The laser source of claim 8, wherein at least one of the first or second coatings comprises a multilayer dielectric coating with a reflection bandwidth of less than 0.5 nm.

12. The laser source of claim 8, wherein the optical resonator comprises only one longitudinal mode within an overlap area between the first and second reflection spectral bands and above a lasing threshold of the laser source.

13. The laser source of claim 8, wherein the first coating has a peak reflectivity of greater than 70%, and the second coating has a peak reflectivity of less than 30%.

14. A display device comprising the laser source of claim 1 as an illuminator.

15. The display device of claim 14, wherein center wavelengths of the first and second reflection spectral bands are offset from one another for narrowing a lasing spectrum of the laser source, wherein the lasing spectrum is in an overlap area between the first and second reflection spectral bands, wherein the overlap area is within the gain spectrum of the gain medium.

16. The display device of claim 15, wherein the laser source comprises a side-emitting laser diode.

17. A side-emitting laser diode comprising:
an optical resonator comprising an output coupler for out-coupling laser emission and a rear reflector opposite the output coupler;
a gain medium in the optical resonator, the gain medium having a gain spectrum;
wherein the rear reflector comprises a first optical interference filter having a reflection spectral band with a bandwidth narrower than 10% of a bandwidth of the gain spectrum above a lasing threshold, for defining a lasing spectrum; and
wherein the output coupler comprises a second optical interference filter having a reflection spectral band with maximum reflectivity of at least 30%.

18. The side-emitting laser diode of claim 17, wherein the bandwidth of the first optical interference filter is less than 0.5 nm FWHM.

19. The side-emitting laser diode of claim 17, wherein center wavelengths of the reflection spectral bands of the first and second optical interference filters are offset from one another for narrowing the lasing spectrum, wherein the lasing spectrum is in an overlap area between the reflection spectral bands, wherein the overlap area is within the gain spectrum of the gain medium.

20. The side-emitting laser diode of claim 17 comprising a laser diode chip, wherein the first and second optical interference filters are disposed on opposite sides of the laser diode chip.
